(19) United States
(12) Patent Application Publication
(10) Pub. No.: US 2023/0189465 A1
(43) Pub. Date: Jun. 15, 2023

(54) ELECTRONIC DEVICE COVERS WITH DYEING LAYERS

(71) Applicant: Hewlett-Packard Development Company, L.P., Spring, TX (US)

(72) Inventors: Kuan-Ting Wu, Taipei City (TW); Ya-Ting Yeh, Taipei City (TW); Chi Hao Chang, Taipei City (TW)

(73) Assignee: Hewlett-Packard Development Company, L.P., Spring, TX (US)

(21) Appl. No.: 17/997,173

(22) PCT Filed: May 13, 2020
(86) PCT No.: PCT/US2020/032703

§ 371 Date: Oct. 26, 2022

(51) Int. Cl. H05K 5/03; C09D 5/00; C09D 7/41; C09D 7/45; C25D 11/02; C25D 11/24; C25D 11/30

(52) U.S. Cl. CPC H05K 5/03; C09D 5/002; C09D 7/41; C09D 7/45; C25D 11/026; C25D 11/30; C25D 11/243

(57) ABSTRACT

The present disclosure is drawn to covers for electronic, devices, methods of making the covers, and electronic devices, in one example, described herein Is a cover for an electronic device comprising: a substrate; a micro-arc oxidation layer applied on at least one surface of the substrate; and a dyeing layer on the micro-arc oxidation layer, wherein the dyeing layer comprises: from about 3 to about 10 wt% wafer based dyes based on the total weight of the dyeing layer; and from about 0.3 wt % to about 2 wt% surfactant based on the total weight of the dyeing layer.

### BACKGROUND

The use of personal electronic devices of all types continues to increase. Cellular phones, including smartphones, have become nearly ubiquitous. Tablet computers have also become widely used in recent years. Portable laptop computers continue to be used by many for personal, entertainment, and business purposes. For portable electronic devices in particular, much effort has been expended to make these devices more useful and more powerful while at the same time making the devices smaller, lighter, and more durable. The aesthetic design of personal electronic devices is also of concern in this competitive market.

### BRIEF DESCRIPTION OF THE DRAWING

FIG. 1 is a cross-sectional view illustrating an example cover for an electronic device in accordance with examples of the present disclosure;

FIG. 2 is a cross-sectional view illustrating another example cover for an electronic device in accordance with examples of the present disclosure;

FIG. 3 is a flowchart illustrating an example method of making a cover for an electronic device in accordance with examples of the present disclosure;

FIG. 4 is a flowchart illustrating another example method of making a cover for an electronic device in accordance with examples of the present disclosure, and

FIG. 5 is a flowchart illustrating another example method of making a cover for an electronic device in accordance with examples of the present disclosure,

### DETAILED DESCRIPTION

A variety of electronic devices can be made with the covers described herein. In various examples, such electronic devices can include various electronic components enclosed by the cover. The electronic device covers can comprise various metals such as magnesium. Magnesium alloy can have limited color stability and can exhibit chemical resistance. As a result, various surface treatment processes are required on magnesium alloy surfaces due to high reactivity and high porosity on the surface. Current methods do not offer effective means of applying and maintaining color coatings on such reactive metal surfaces of substrates forming electronic device covers.

In this disclosure, covers for electronic devices, methods of making the covers, and electronic devices, are described that comprise metal substrates with color coatings while still offering light weight, high hardness, durable, and corrosion resistant features of metal substrates.

In some examples, described herein is a cover for an electronic device comprising: a substrate; a micro-arc oxidation layer applied on at least one surface of the substrate; and a dyeing layer on the micro-arc oxidation layer, wherein the dyeing layer comprises: from about 3 to about 10 wt% water based dyes based on the total weight of the dyeing layer; and from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof.

In some examples, the substrate comprises aluminum and aluminum alloys, titanium and titanium alloys, stainless steel, magnesium and magnesium alloys, lithium and lithium alloys, zinc and zinc alloys, niobium and niobium alloys, copper and copper alloys, carbon fiber composite, or combinations thereof.

In some examples, the cover of claim further comprises a painting layer on the dyeing layer.

In some examples, the micro-arc oxidation layer comprises forming an oxide coating using an electrolytic solution selected from the group consisting of sodium silicate, sodium phosphate, potassium fluoride, potassium hydroxide, sodium hydroxide, fluorozirconate, sodium hexametaphosphate, sodium fluoride aluminum oxide, silicon dioxide, ferric ammonium oxalate, a salt of phosphoric acid, polyethylene oxide alkylphenolic ether, and combinations thereof, and the micro-arc oxidation layer has a thickness of from about 2 µm to about 15 µm.

In some examples, the dyeing layer has a thickness of from about 1 µm to about 5 µm.

In some examples, the water based dyes are selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41(C,I. 11105), C.l. acid blue 45, acid dye, alkaline dye, and combinations thereof.

In some examples, the painting layer has a thickness of from about 1 µm to about 25 µm, and the painting layer comprises: a primer layer, a base coat layer, and a top coat layer and/or an anti-fingerprint coat layer.

In some examples, disclosed herein is an electronic device comprising: an electronic component; and a cover enclosing the electronic component, the cover comprising: a substrate, wherein the substrate comprises aluminum and aluminum alloys, titanium and titanium alloys, stainless steel, magnesium and magnesium alloys, lithium and lithium alloys, zinc and zinc alloys, niobium and niobium alloys, copper and copper alloys, carbon fiber composite, or combinations thereof; a micro-arc oxidation layer applied on at least one surface of the substrate; and a dyeing layer on the micro-arc oxidation layer, wherein the dyeing layer comprises from about 3 to about 10 wt% water based dyes based on the total weight of the dyeing layer; and from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof.

In some examples, the electronic device is a laptop, a desktop computer, a keyboard, a mouse, a smartphone, a tablet, a monitor, a television screen, a speaker, a game console, a video player, an audio player, or a combination thereof.

In some examples, the water based dyes are selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41 (C.I. 11105), C.I. acid blue 45, acid dye, alkaline dye, and combinations thereof.

In some examples, the cover further comprises a painting layer on the dyeing layer.

In some examples, the painting layer has a thickness of from about 1 µm to about 25 µm.

In some examples, the painting layer comprises: a primer layer, a base coat layer, and a top coat layer and/or an anti-fingerprint coat layer.

In some examples, disclosed herein is a method of making a cover for an electronic device comprising: applying a micro-arc oxidation layer on at least one surface of a substrate comprising a metal; applying a dyeing layer on the micro-arc oxidation layer at a temperature of from about 30° C. to about 80° C., wherein the dyeing layer comprises: from about 3 to about 10 wt% water based dyes based on the total weight of the dyeing layer; from about 0.3 wt% to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof, and applying an optional painting layer on the dyeing layer.

In some examples, the dyeing layer has a thickness of from about 1 µm to about 5 µm; and the water based dyes are selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41 (C.I. 11105), C.I. acid blue 45, acid dye, alkaline dye, and combinations thereof.

### Covers for Electronic Devices

The present disclosure describes covers for electronic devices that can be strong and lightweight and have a decorative appearance. In some cases, light metal materials can be used to make covers for electronic devices. Generally, light metals can include aluminum, magnesium, titanium, lithium, niobium, zinc, and alloys thereof. Covers can also be made from stainless steel or a carbon fiber composite in some cases. These materials can have useful properties, such as low weight, high strength, and an appealing appearance. However, some of these metals can be easily oxidized at the surface, and may be vulnerable to corrosion or other chemical reactions at the surface. For example, magnesium or magnesium alloys in particular can be used to form covers for electronic devices because of the low weight and high strength of magnesium. Magnesium can have a somewhat porous surface that can be vulnerable to chemical reactions and corrosion at the surface. In some examples, magnesium or magnesium alloy can be treated by micro-arc oxidation to form a layer of protective oxide at the surface. This protective oxide layer can increase the chemical resistance, hardness, and durability of the magnesium or magnesium alloy. However, micro-arc oxidation can also create a dull appearance instead of the original luster of the metal.

The present disclosure describes covers for electronic devices that can utilize the above metals for their favorable properties and at the same time the metals can be protected from corrosion. Furthermore, the covers can have an attractive appearance. In some cases, it can be desirable to chamfer certain edges of the cover for ergonomics and/or to enhance the appearance of the cover. Some examples of edges that may be chamfered can include an edge surrounding a trackpad on a laptop, an edge surrounding a fingerprint scanner, an outer edge of a smartphone housing or cover, and so on.

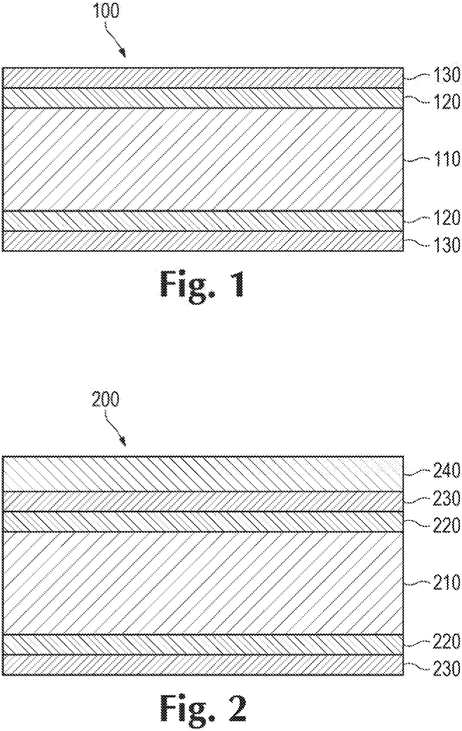

FIG. 1 is a cross-sectional view illustrating an example cover 100 for an electronic device. The cover 100 comprises a substrate 110; a micro-arc oxidation layer 120 applied on at least one surface of the substrate; and a dyeing layer 130 on the micro-arc oxidation layer, wherein the dyeing layer comprises: from about 3 to about 10 wt% water based dyes based on the total weight of the dyeing layer; and from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof.

FIG. 2 is a cross-sectional view illustrating another example cover 200 for an electronic device. The cover 200 comprises a substrate 210; a micro-arc oxidation layer 220 applied on at least one surface of the substrate; a dyeing layer 230 on the micro-arc oxidation layer, wherein the dyeing layer comprises: from about 3 to about 10 wt% water based dyes based on the total weight of the dyeing layer; and from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof; and a painting layer 240 on the dyeing layer.

As used herein, “cover” refers to the exterior shell of an electronic device. In other words, the cover contains the internal electronic components of the electronic device. The cover is an integral part of the electronic device. The term “cover” is not meant to refer to the type of removable protective cases that are often purchased separately for an electronic device (especially smartphones and tablets) and placed around the exterior of the electronic device. Covers as described herein can be used on a variety of electronic devices. For example, laptop computers, smartphones, tablet computers, and other electronic devices can include the covers described herein. In various examples, the metal cover substrates for these covers can be formed by molding, casting, machining, bending, working, stamping, or another process. In one example, a metal cover substrate can be milled from a single block of metal. In other examples, the cover can be made from multiple panels. For example, laptop covers sometimes include four separate cover pieces forming the complete cover of the laptop. The four separate pieces of the laptop cover are often designated as cover A (back cover of the monitor portion of the laptop), cover B (front cover of the monitor portion), cover C (top cover of the keyboard portion) and cover D (bottom cover of the keyboard portion). Covers can also be made for smartphones and tablet computers with a single metal piece or multiple metal panels.

As used herein, a layer that is referred to as being “on” a lower layer can be directly applied to the lower layer, or an intervening layer or multiple intervening layers can be located between the layer and the lower layer. Generally, the covers described herein can include a metal cover substrate and a micro-arc oxidation layer on a surface of the metal cover substrate. Accordingly, a layer that is “on” a lower layer can be located further from the metal cover substrate. However, in some examples there may be other intervening layers such as a primer coating layer underneath the micro-arc oxidation layer. Thus, a “higher” layer applied “on” a “lower” layer may be located farther from the metal cover substrate and closer to a viewer viewing the cover from the outside.

It is noted that when discussing covers for electronic devices, the electronic devices themselves, or methods of making covers for electronic devices, such discussions can be considered applicable to one another whether or not they are explicitly discussed in the context of that example. Thus, for example, when discussing the metals used in the metal cover substrate in the context of one of the example covers, such disclosure is also relevant to and directly supported in the context of the electronic devices and/or methods, and vice versa. It is also understood that terms used herein will take on their ordinary meaning in the relevant technical field unless specified otherwise, In some instances, there are terms defined more specifically throughout or included at the end of the present disclosure, and thus, these terms are supplemented as having a meaning described herein.

### Electronic Devices

A variety of electronic devices can be made with the covers described herein, In various examples, such electronic devices can include various electronic components enclosed by the cover. As used herein, “encloses” or “enclosed” when used with respect to the covers enclosing electronic components can include covers completely enclosing the electronic components or partially enclosing the electronic components. Many electronic devices include openings for charging ports, input/output ports, headphone ports, and so on. Accordingly, in some examples the cover can include openings for these purposes. Certain electronic components may be designed to be exposed through an opening in the cover, such as display screens, keyboard keys, buttons, track pads, fingerprint scanners, cameras, and so on. Accordingly, the covers described herein can include openings for these components, Other electronic components may be designed to be completely enclosed, such as motherboards, batteries, sim cards, wireless transceivers, memory storage drives, and so on. Additionally, in some examples a cover can be made up of two or more cover sections, and the cover sections can be assembled together with the electronic components to enclose the electronic components. As used herein, the term “cover” can refer to an individual cover section or panel, or collectively to the cover sections or panels that can be assembled together with electronic components to make the complete electronic device.

In some examples, the electronic devices can be personal computers, laptops, tablet computers, e-readers, music players, smartphones, mouse, keyboards, or a variety of other types of electronic devices. In certain examples, the chamfered edge or edges can be located in decorative locations on the cover. Some examples include chamfered edges around track pads, around fingerprint scanners, at outer edges of the cover, at an edge of a sidewall, at an edge of a logo, and so on.

### Methods of Making Covers for Electronic Devices

In some examples, the covers described herein can be made by first forming the metal cover substrate. This can be accomplished using a variety of processes, including molding, forging, casting, machining, stamping, bending, working, and so on. The metal cover substrate can be made from a variety of metals. In certain examples, the metal cover substrate can include aluminum, magnesium, lithium, titanium, zinc, niobium, stainless steel, or an alloy thereof. As mentioned above, in some examples the metal cover substrate can be a single piece while in other examples the metal cover substrate can include multiple pieces that each makes up a portion of the cover. Additionally, in some examples the metal cover substrate can be a composite made up of multiple metals combined, such as having layers of multiple different metals or panels or other portions of the metal cover substrate being different metals, Plastic can then be insert molded onto at least one surface of the metal substrate.

A micro-arc oxidation layer can be applied to any surface of the metal cover substrate, including fully or partially covering a single surface, fully or partially covering multiple surfaces, or fully or partially covering the metal cover substrate as a whole. The micro-arc oxidation layer can be applied by any suitable application method.

In some examples, a dyeing layer can be applied on the micro-arc oxidation layer. A painting layer can be applied on the dyeing layer.

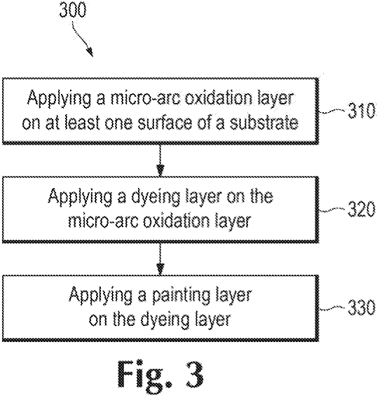

FIG. 3 is a flowchart illustrating an example method 300 of making a cover for an electronic device. The method comprises applying a micro-arc oxidation layer 310 on at least one surface of a substrate comprising a metal; applying a dyeing layer 320 on the micro-arc oxidation layer at a temperature of from about 30° C. to about 80° C., wherein the dyeing layer comprises: from about 3 to about 10 wt% water based dyes based on the total weight of the dyeing layer; from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof, and applying a painting layer 330 on the dyeing layer.

### Metal Cover Substrate

In some examples, the metal cover substrate comprises aluminum and aluminum alloys, titanium and titanium alloys, stainless steel, magnesium and magnesium alloys, lithium and lithium alloys, zinc and zinc alloys, niobium and niobium alloys, copper and copper alloys, carbon fiber composite, or combinations thereof.

The metal cover substrate can be made from a single metal, a metallic alloy, a combination of sections made from multiple metals, or a combination of metal and other materials. In some examples, the metal cover substrate can include a light metal. In certain examples, the metal cover substrate can include aluminum, magnesium, lithium, titanium, zinc, niobium, stainless steel, or an alloy thereof. In further particular examples, the metal cover substrate can include aluminum, an aluminum alloy, magnesium, or a magnesium alloy. Non-limiting examples of elements that can be included in aluminum or magnesium alloys can include aluminum, magnesium, titanium, lithium, niobium, zinc, bismuth, copper, cadmium, iron, thorium, strontium, zirconium, manganese, nickel, lead, silver, chromium, silicon, tin, gadolinium, yttrium, calcium, antimony, cerium, lanthanum, or others.

In some examples, the metal cover substrate can include an aluminum magnesium alloys made up of about 0.5% to about 13% magnesium by weight and 87% to 99.5% aluminum by weight. Examples of specific aluminum magnesium alloys can include 575, 1050, 1060, 1100, 1199, 2014, 2024, 2219, 3004, 4041, 5005, 5010, 5019, 5024, 5026, 5050, 5052, 5056, 5059, 5083, 5086, 5154, 5182, 5252, 5254, 5356, 5454, 5456, 5457, 5557, 5652, 5657, 5754, 6005, 6005A, 6060, 6061, 6063, 6066, 6070, 6082, 6105, 6151, 6162, 6205, 6262, 6351, 6463, 7005, 7022, 7068, 7072, 7075, 7079, 7116, 7129, 7175, 7475, and 7178.

In further examples, the metal cover substrate can include magnesium metal, a magnesium alloy that is 99% or more magnesium by weight, or a magnesium alloy that is from about 50% to about 99% magnesium by weight. In a particular example, the metal cover substrate can include an alloy including magnesium and aluminum. Examples of magnesium-aluminum alloys can include alloys made up of from about 91% to about 99% magnesium by weight and from about 1% to about 9% aluminum by weight, and alloys made up of about 0.5% to about 13% magnesium by weight and 87% to 99.5% aluminum by weight. Specific examples of magnesium-aluminum alloys can include AZ63, AZ81, AZ91, AZ92, AM50, AM60, AM100, AZ31, AZ61, AZ63, AZ80, AE44, AJ62A, ALZ391, ALZ691, ALZ991, AMCa602, LZ91, LZ141, and Magnox.

The metal cover substrate can be shaped to fit any type of electronic device, including the specific types of electronic devices described herein. In some examples, the metal cover substrate can have any thickness suitable for a particular type of electronic device. The thickness of the metal in the metal cover substrate can be selected to provide a desired level of strength and weight for the cover of the electronic device. In some examples, the metal cover substrate can have a thickness from about 0.3 mm to about 2 cm, or from about 0.5 mm to about 1.5 cm, or from about 1 mm to about 1.5 cm, or from about 1.5 mm to about 1.5 cm, or from about 2 mm to about 1 cm, or from about 3 mm to about 1 cm, or from about 4 mm to about 1 cm, or from about 1 mm to about 5 mm, though thicknesses outside of these ranges can be used.

In still further examples, the metal cover substrate can include a metal having a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt% to about 15 wt% electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt% to about 3.5 wt%, or from about 2 wt% to about 3 wt%, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be about 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used. This process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 µm or more.

In some examples the oxide layer can have a thickness from about 1 µm to about 25 µm, from about 1 µm to about 22 µm, or from about 2 µm to about 20 µm. Thickness can likewise be from about 2 µm to about 15 µm, or from about 3 µm to about 10 µm, or from about 4 µm to about 7 µm. The oxide layer can, in some instances, enhance the mechanical, wear, thermal, dielectric, and corrosion properties of the substrate. The electrolyte solution can include a variety of electrolytes, such as a solution of potassium hydroxide. In some examples, the metal cover substrate can include a micro-arc oxidation layer on one side, or on both sides.

### Degreasing

In some examples, degreasing can be a pre-treatment step. The pre-treatment composition is applied to at least one surface of the substrate, wherein the pre-treatment composition comprises ethylenediamine tetraacetic acid; ethylenediamine; nitrolotriacetic acid; diethylenetriaminepenta(methylenephosphonic acid); nitrolotris(methylenephosphonic acid); 1-hydroxyethane-1,1-diphosphonic acid; sulfuric acid and phosphoric acid in combination with aluminum ions, nickel ions, chromium ions, tin ions, or zinc ions; or combinations thereof.

In certain examples, degreasing can be carried out using an alkaline cleaning process used to remove debris from a surface of the metal alloy. Degreasing can include submerging the substrate surface in or applying on the substrate surface to be cleaned a cleaning solution including water and from about 0.3 wt% to about 2.0 wt% of sodium caseinate, sodium polyacrylate, sodium polyoxyethylene alkyl ether carboxylate, sodium dodecyl sulfate, or a mixture thereof for a time period ranging from about 30 seconds to about 180 seconds.

### Micro-arc Oxidation Layer

In some examples, the micro-arc oxidation layer is formed by plasma electrolytic oxidation of the surface of the metal cover substrate.

In still further examples, the rigid substrate can include a metal having a micro-arc oxidation layer on a surface thereof. Micro-arc oxidation, also known as plasma electrolytic oxidation, is an electrochemical process where the surface of a metal is oxidized using micro-discharges of compounds on the surface of the substrate when immersed in a chemical or electrolytic bath, for example. The electrolytic bath may include predominantly water with about 1 wt% to about 15 wt% electrolytic compound(s), e.g., alkali metal silicates, alkali metal hydroxide, alkali metal fluorides, alkali metal phosphates, alkali metal aluminates, the like, and combinations thereof. The electrolytic compounds may likewise be included at from about 1.5 wt% to about 3.5 wt%, or from about 2 wt% to about 3 wt%, though these ranges are not considered limiting. In one example, a high-voltage alternating current can be applied to the substrate to create plasma on the surface of the substrate. In this process, the substrate can act as one electrode immersed in the electrolyte solution, and the counter electrode can be any other electrode that is also in contact with the electrolyte. In some examples, the counter electrode can be an inert metal such as stainless steel. In certain examples, the bath holding the electrolyte solution can be conductive and the bath itself can be used as the counter electrode. A high direct current or alternating voltage can be applied to the substrate and the counter electrode. In some examples, the voltage can be 200 V or higher, such as about 200 V to about 600 V, about 250 V to about 600 V, about 250 V to about 500 V, or about 200 V to about 300 V. Temperatures can be from about 20° C. to about 40° C., or from about 25° C. to about 35° C., for example, though temperatures outside of these ranges can be used.

The above process can oxidize the surface to form an oxide layer from the substrate material. Various metal or metal alloy substrates can be used, including aluminium, titanium, lithium, magnesium, and/or alloys thereof, for example. The oxidation can extend below the surface to form thick layers, as thick as 30 µm or more.

In some examples the oxide layer can have a thickness from about 2 µm to about 15 µm, from about 5 µm to about 10 µm, or less than about 15 µm.

The oxide layer can, in some instances, enhance the mechanical, wear, thermal, dielectric, and corrosion properties of the substrate. The electrolyte solution can include a variety of electrolytes, such as a solution of potassium hydroxide. In some examples, the rigid substrate can include a micro-arc oxidation layer on one side, or on both sides.

### Dyeing Layer

In some examples, the dyeing layer is applied over the micro-arc oxidation layer.

The dyeing layer comprises from about 3 to about 10 wt% water based dyes based on the total weight of the dyeing layer; and from about 0.3 wt % to about 2 wt% surfactant based on the total weight of the dyeing layer. In some examples, the dyeing layer comprises from about 4 to about 9 wt% water based dyes based on the total weight of the dyeing layer; and from about 0.5 wt % to about 1.5 wt% surfactant based on the total weight of the dyeing layer. In some examples, the dyeing layer comprises from about 5 to about 8 wt% water based dyes based on the total weight of the dyeing layer; and less than about 2 wt% surfactant based on the total weight of the dyeing layer. In some examples, the dyeing layer comprises less than about 10 wt% water based dyes based on the total weight of the dyeing layer; and greater than about 0.1 wt% surfactant based on the total weight of the dyeing layer.

The surfactant can be selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof.

The dyeing layer can have a thickness of from about 1 µm to about 5 µm, or less than about 5 µm, or greater than about 1 µm.

The water based dyes can be selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41 (C.I. 11105), C.I. acid blue 45, acid dye, alkaline dye, and combinations thereof.

In some examples, the dyeing layer can be applied by application of any spraying means including spray coating, thermal ink jetting, piezo ink jetting, electrostatic application, or any other similar application method on to the micro-arc oxidation layer on the substrate. In some examples, the dyeing layer can be applied by a variety of application processes, such as spin coating, dipping, spraying, spreading, and so on.

### Painting Layer

In some examples, after the dyeing layer a painting layer can be applied. This painting layer can include a primer layer, a base coat layer, and a top coat layer and/or an anti-fingerprint coat layer.

The painting layer can have a thickness of from about 1 µm to about 25 µm.

### Primer Coating, Base Coating, Top Coating Layers

In some examples, covers described and prepared herein can include a coating (or application of coating), such as by application of a spray coating or electrostatically-applied coating to a surface of the metal. The coating can provide an aesthetic appeal and/or protection to the cover. Spray coating can be used to apply a primer coat, a base coat, a top coat and/or an anti-fingerprint coat layer, or a combination thereof. Electrostatic coating can be used to a powder coat. Sprayed coatings can be applied as primer coatings, base coatings, top coatings, etc.

### Primer Coat

In some examples, the primer coating layer can comprise polyurethane, silicone-polyurethane copolymer, polyurethane-polystyrene copolymer, polyurethane based copolymers, polyester, epoxy, epoxy-polyester, and combinations thereof.

A primer coat, for example, can include a polyester, polyurethane, or a combination thereof that can be applied to a surface of the metal substrate. The primer coat can be cured by baking the surface at a temperature that can range from about 60° C. to about 80° C. for a time period that can range from about 15 minutes to about 40 minutes.

The primer coating layer may comprise at least one of a polyurethane or a filler selected from carbon black, titanium dioxide, clay, mica, talc, barium sulfate, calcium carbonate, a synthetic pigment, a metallic powder, aluminum oxide, carbon nanotubes (CNTs), graphene, graphite, or an organic powder or a combination thereof. The primer may comprise a polyurethane and a filler. In an example, the primer coating layer is a polyester polyurethane.

The primer coating layer may have a thickness of less than about 25 µm, or less than about 20 µm, or less than about 15 µm, or less than about 12.5 µm, or less than about 10 µm, or less than about 8 µm, or less than about 5 µm. The thickness of the primer coating layer can be measured after it has been printed using, for example, a micrometre screw gauge or scanning electron microscope (SEM).

In some examples the primer coating layer is thicker than the base coating layer or the top coating layer.

### Base Coat

In some examples, the base coating layer can comprise polyurethane, silicone-polyurethane copolymer, polyurethane-polystyrene copolymer, polyurethane based copolymers, polyester, epoxy, epoxy-polyester, and combinations thereof.

A base coat can include polyester, polyurethane and polyurethane copolymers with pigments including carbon black, titanium dioxide, clay, mica, talc, barium sulfate, calcium carbonate, synthetic pigment, metallic powder, aluminum oxide, organic powder, inorganic powder, plastic bead, color pigment, dye, or any combination thereof. The base coat can be cured by baking the surface of the metal substrate at a temperature ranging from about 60° C. to about 80° C. for a time period ranging from about 15 minutes to about 40 minutes.

In some examples, a base coat can include a polyester, a polyurethane, or a copolymer thereof. In one example, a top coat can include a polyurethane, a polyacrylic or polyacrylate, a urethane, an epoxy, or a copolymer thereof. The paint coating can be any number of colors and can be transparent, semi-transparent, or opaque.

In some examples, the base coating layer may comprise polyurethane-containing pigments. The base coating layer may further comprise at least one of carbon black, titanium dioxide, clay, mica, talc, barium sulfate, calcium carbonate, synthetic pigment, metallic powder, aluminum oxide, an organic powder, an inorganic powder, graphene, graphite, plastic beads, a color pigment or a dye. The organic powder may, for example, be an acrylic, a polyurethane, a polyamide, a polyester or an epoxide. In some examples, the base coating layer may further comprise a component selected from barium sulfate, talc, a dye and a color pigment. In one example, the base coating layer comprises a color pigment or a dye. In some examples, the base coating layer may further comprise a heat resistant material, such as a silica aerogel. The base coating layer can comprise a heat resistant material and a component as described above.

In some examples, the base coating layer has a thickness of less than about 25 µm, or less than about 20 µm, or less than about 15 µm, or less than about 12.5 µm, or less than about 10 µm, or less than about 8 µm,or less than about 5 µm, The thickness of the primer coating layer can be measured after it has been printed using, for example, a micrometre screw gauge or SEM. Top Coat

In some examples, the top coating layer comprises acrylate epoxy, acrylate urethane, acrylate polyether, acrylate polyester, polyester, polyurethane, and combinations thereof.

In some examples, the top coating layer comprises nanosized and/or coarse high refractive index pigments having a Mohs hardness of about ≥ 5, or of about ≥ 6, or of about ≥ 7, or of about ≥ 8, or of about ≥ 8, or of about ≥ 9, or of about ≤ 10,

A top coat can include a polyurethane coat and/or an ultra-violet coat. A polyurethane coat can include a polyurethane, a polyurethane copolymer, or both a polyurethane and a polyurethane copolymer. The polyurethane coat can be cured at a temperature that can range from about 60° C. to about 80° C. for a time period that can range from about 15 minutes to about 40 minutes. An ultra-violet coat can include a polyacrylic, a polyurethane, a urethane acrylate, an acrylic acrylate, an epoxy acrylate, or any combinations thereof. The ultra-violet coat can be cured at temperature that can range from about 50° C. to about 60° C., for a time period of from about 10 minutes to about 15 minutes, followed by UV exposure to a light having an energy ranging from about 700 mJ/cm² to about 1,200 mJ/cm² for from about 10 seconds to about 30 seconds. The polyurethane coat, the ultra-violet coat, or both the polyurethane coat and the ultra-violet coat can be independently applied at a thickness that can range from about 10 µm to about 25 µm,

In some examples, the top coating layer is a heat-sensitive or UV-curable resin. The top coating layer may comprise at least one of a polyacrylic resin, a polyurethane resin or polymer, a urethane acrylate resin, an acrylic acrylate resin or an epoxy acrylate resin, or a combination thereof.

In some examples, the top coating layer has a thickness of less than about 25 µm, or less than about 20 µm, or less than about 15 µm, or less than about 12.5 µm, or less than about 10 µm, or less than about 8 µm, or less than about 5 µm. The thickness of the primer coating layer can be measured after it has been printed using, for example, a micrometre screw gauge or SEM. Anti-fingerprint Coating

An anti-fingerprint layer can be applied over the base coat or the top coat, The anti-fingerprint layer can include an ultraviolet radiation-cured polymer mixed with an anti-fingerprint material. Anti-fingerprint materials can include materials such as silanes, fluorinated polymers, and hydrophobic polymers.

A specific example silane is hexadecyl trimethoxy silane. In specific examples, the anti-fingerprint material can include a fluorinated polyolefin, a fluoroacrylate, a fluorosilicone acrylate, a fluorourethane, a perflouropolyether, a perfluoropolyoxetane, a fluorotelomer, polytetrafluoroethylene, polyvinylidenefluoride, a fluorosiloxane, a fluorinated ultraviolet radiation-curable polymer, or a combination thereof. In certain examples, fluorotelomers can be C-6 or lower in size.

In other examples, the anti-fingerprint material can be a hydrophobic polymer that is C-7 or greater in size. In further examples, the ultraviolet radiation-curable polymer in the anti-fingerprint layer can include a polyacrylic, a polyurethane, a urethane acrylate, an acrylic acrylate, an epoxy acrylate, or a combination thereof.

In some examples, the mixture can include the anti-fingerprint material in an amount of about 5 wt% to about 25 wt% and the remainder can be the ultraviolet radiation-curable resin. In further examples, the amount of the anti-fingerprint material can be from about 5 wt% to about 15 wt% or from about 15 wt% to about 25 wt%.

The mixture of the ultraviolet radiation-curable resin and the anti-fingerprint material can be applied to the surface of the coated substrate by a variety of application processes, such as spin coating, dipping, spraying, spreading, and so on. The composition can then be cured by exposure to UV radiation. In certain examples, the composition can be baked at a temperature from about 50° C. to about 60° C. for a period of time from about 10 minutes to about 15 minutes before exposure to UV radiation.

After baking, the layer can be exposed to UV radiation at an intensity from about 700 mJ/cm² to about 1,200 mJ/cm². In other examples the UV radiation intensity can be from about 800 mJ/cm² to about 1,100 mJ/cm², The irradiation time can be from about 10 seconds to about 30 seconds in some examples. In other examples, the irradiation time can be from about 10 seconds to about 20 seconds, or from about 20 seconds to about 30 seconds.

### Definitions

It is noted that, as used in this specification and the appended claims, the singular forms “a,” “an,” and “the” include plural referents unless the content clearly dictates otherwise.

As used herein, the term “about” is used to provide flexibility to a numerical range endpoint by providing that a given value may be “a little above” or “a little below” the endpoint. The degree of flexibility of this term can be dictated by the particular variable based on experience and the associated description herein.

As used herein, a plurality of items, structural elements, compositional elements, and/or materials may be presented in a common list for convenience. However, these lists should be construed as though individual members of the list are individually identified as a separate and unique member. Thus, no individual member of such list should be construed as a de facto equivalent of any other member of the same list solely based on their presentation in a common group without indications to the contrary.

Concentrations, dimensions, amounts, and other numerical data may be presented herein in a range format. It is to be understood that such range format is used merely for convenience and brevity and should be interpreted flexibly to include the numerical values explicitly recited as the limits of the range, but also all the individual numerical values or sub-ranges encompassed within that range as if individual numerical values and sub-ranges are explicitly recited. For example, an atomic ratio range of about 1 at% to about 20 at% should be interpreted to include the explicitly recited limits of about 1 at% and about 20 at%, but also to include individual atomic percentages such as 2 at%, 11 at%, 14 at%, and sub-ranges such as 10 at% to 20 at%, 5 at% to 15 at%, etc.

The terms, descriptions, and figures used herein are set forth by way of illustration and are not meant as limitations. Many variations are possible within the disclosure, which is intended to be defined by the following claims -- and equivalents -- in which all terms are meant in the broadest reasonable sense unless otherwise indicated.

### EXAMPLES

The following illustrates examples of the present disclosure. However, it is to be understood that the following are merely illustrative of the application of the principles of the present disclosure. Numerous modifications and alternative devices, methods, and systems may be devised without departing from the spirit and scope of the present disclosure. The appended claims are intended to cover such modifications and arrangements.

### Prophetic Example 1 - Forming a Coated Metal Substrate

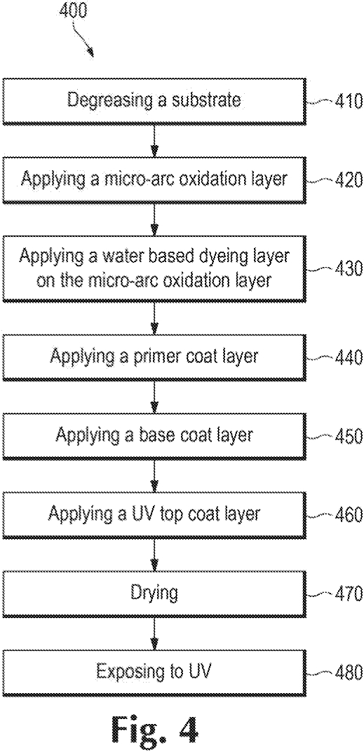

FIG. 4 is a flowchart illustrating an example method 400 of making a cover for an electronic device. The method comprises:
degreasing at least one surface of a substrate comprising magnesium alloy -410;
applying a micro-arc oxidation layer on the degreased surface of the substrate
420;
applying a dyeing layer on the micro-arc oxidation layer at a temperature of from about 30° C. to about 80° C. for from about 3 minutes to about 15 minutes -430;
applying a painting layer by first applying a primer coat layer on the dyeing layer at a temperature of from about 60° C. to about 80° C. for from about 30 minutes to about 60 minutes - 440, then applying a base coat layer at a temperature of from about 60° C. to about 80° C. for from about 30 minutes to about 60 minutes - 450, and then applying a UV top coat layer - 460;
drying the coated substrate in air at a temperature of from about 50° C. to about 60° C. for from about 5 minutes to about 10 minutes - 470; and
exposing the dried coated substrate to ultraviolet light for from about 10 seconds to about 30 seconds at 700 to 1,200 mJ/cm² - 480.

The resulting cover can have a schematic cross-sectional appearance as shown in FIG. 2.

### Prophetic Example 2 - Forming a Coated Metal Substrate

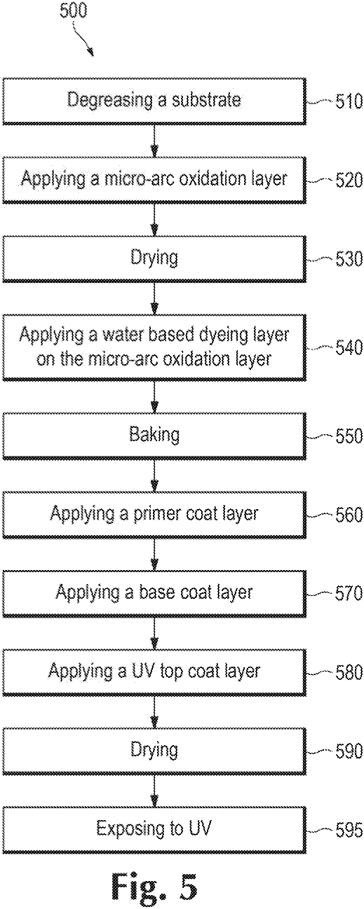

FIG. 5 is a flowchart illustrating an example method 500 of making a cover for an electronic device. The method comprises:
degreasing at least one surface of a substrate comprising magnesium alloy 510;
applying a micro-arc oxidation layer on the degreased surface of the substrate 520:
drying the coated substrate in air at a temperature of from about 60″C to about 105° C. for from about 10 minutes to about 15 minutes - 530;
applying a dyeing layer on the micro-arc oxidation layer at a temperature of from about 30° C. to about 80° C. for from about 3 minutes to about 15 minutes - 540;
baking the coated substrate in air at a temperature of from about 80° C. to about 120° C. for from about 15 minutes to about 40 minutes - 550;
applying a painting layer by first applying a primer coat layer on the dyeing layer at a temperature of from about 60° C. to about 80° C. for from about 30 minutes to about 60 minutes - 560, then applying a base coat layer at a temperature of from about 60° C. to about 80° C. for from about 30 minutes to about 60 minutes - 570, and then applying a UV top coat layer - 580;
drying the coated substrate in air at a temperature of from about 50° C. to about 60° C. for from about 5 minutes to about 10 minutes - 590; and
exposing the dried coated substrate to ultraviolet light for from about 10 seconds to about 30 seconds at 700 to 1,200 mJ/cm² - 595.

The resulting cover can have a schematic cross-sectional appearance as shown in FIG. 2.

What is claimed is:

1. A cover for an electronic device comprising:
a substrate;
a micro-arc oxidation layer applied on at least one surface of the substrate; and
a dyeing layer on the micro-arc oxidation layer, wherein the dyeing layer comprises:
from about 3 to about 10 wt% water based dyes based on the total weight of the dyeing layer; and
from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof.

2. The cover of claim 1, wherein the substrate comprises aluminum and aluminum alloys, titanium and titanium alloys, stainless steel, magnesium and magnesium alloys, lithium and lithium alloys, zinc and zinc alloys, niobium and niobium alloys, copper and copper alloys, carbon fiber composite, or combinations thereof.

3. The cover of claim 1 further comprises a painting layer on the dyeing layer.

4. The cover of claim 1, wherein:
the micro-arc oxidation layer comprises forming an oxide coating using an electrolytic solution selected from the group consisting of sodium silicate, sodium phosphate, potassium fluoride, potassium hydroxide, sodium hydroxide, fluorozirconate, sodium hexametaphosphate, sodium fluoride aluminum oxide, silicon dioxide, ferric ammonium oxalate, a salt of phosphoric acid, polyethylene oxide alkylphenolic ether, and combinations thereof, and
the micro-arc oxidation layer has a thickness of from about 2 µm to about 15 µm.

5. The cover of claim 1, wherein the dyeing layer has a thickness of from about 1 µm to about 5 µm.

6. The cover of claim 1, wherein the water based dyes are selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41 (C.l. 11105), C.l. acid blue 45, acid dye, alkaline dye, and combinations thereof.

7. The cover of claim 3,
wherein the painting layer has a thickness of from about 1 µm to about 25 µm, and
wherein the painting layer comprises:
a primer layer,
a base coat layer, and
a top coat layer and/or an anti-fingerprint coat layer.

8. An electronic device comprising:
an electronic component; and
a cover enclosing the electronic component, the cover comprising:
a substrate, wherein the substrate comprises aluminum and aluminum alloys, titanium and titanium alloys, stainless steel, magnesium and magnesium alloys, lithium and lithium alloys, zinc and zinc alloys, niobium and niobium alloys, copper and copper alloys, carbon fiber composite, or combinations thereof;
a micro-arc oxidation layer applied on at least one surface of the substrate; and
a dyeing layer on the micro-arc oxidation layer, wherein the dyeing layer comprises:
from about 3 to about 10 wt% water based dyes based on the total weight of the dyeing layer; and
from about 0.3 wt % to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof.

9. The electronic device of claim 8, wherein the electronic device is a laptop, a desktop computer, a keyboard, a mouse, a smartphone, a tablet, a monitor, a television screen, a speaker, a game console, a video player, an audio player, or a combination thereof.

10. The electronic device of claim 8, wherein the water based dyes are selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41 (C.l. 11105), C.l. acid blue 45, acid dye, alkaline dye, and combinations thereof.

11. The electronic device of claim 8, wherein the cover further comprises a painting layer on the dyeing layer.

12. The electronic device of claim 12, wherein the painting layer has a thickness of from about 1 µm to about 25 µm.

13. The electronic device of claim 12, wherein the painting layer comprises:a primer layer,
a primer layer,
a base coat layer, and
a top coat layer and/or an anti-fingerprint coat layer.

14. A method of making a cover for an electronic device comprising:
applying a micro-arc oxidation layer on at least one surface of a substrate comprising a metal;
applying a dyeing layer on the micro-arc oxidation layer at a temperature of from about 30° C. to about 80° C., wherein the dyeing layer comprises: from about 3 to about 10 wt% water based dyes based on the total weight of the dyeing layer; from about 0.3 wt% to about 2 wt% surfactant based on the total weight of the dyeing layer, wherein the surfactant is selected from the group consisting of alcohol sulfates, alkylbenzene sulfonates, sodium caseinate, sodium polyacrylate, sodium polyoxyethylene alkyl ether carboxylate, sodium silicate, sodium hexmetaphoate, sodium dodecyl sulfate, and combinations thereof; and
applying an optional painting layer on the dyeing layer.

15. The method of claim 14, wherein
the dyeing layer has a thickness of from about 1 µm to about 5 µm; and
the water based dyes are selected from the group consisting of methylene blue, basic fuchsin, crystal violet, eosin, acid fuchsin, congo red, gentian violet, methyl violet, brilliant crystal glue, Romanowsky dye, anthraquinone dyes, acridine orange, quinone-imine dyes, xanthene dyes, 2-amino-4-(azoyl)-azo-thiazole, basic blue 41 (C.l. 11105), C.l. acid blue 45, acid dye, alkaline dye, and combinations thereof.
